(19) United States
(12) Patent Application Publication
(10) Pub. No.: US 2024/0258966 A1
(43) Pub. Date: Aug. 1, 2024

(54) Arc Detection and Prevention in a Power Generation System

(71) Applicant: Solaredge Technologies Ltd., Herzeliya (IL)

(72) Inventors: Ilan Yoscovich, Givatayim (IL); Guy Sella, Bitan Aharon (IL); Meir Gazit, Ashkelon (IL); Yoav Galin, Raanana (IL); David Braginsky, Yokne'am (IL); Lior Handelsman, Givatayim (IL); Meir Adest, Modiin (IL)

(21) Appl. No.: 18/636,114

(22) Filed: Apr. 15, 2024

Related U.S. Application Data
(63) Continuation of application No. 17/732,772, filed on Apr. 29, 2022, now Pat. No. 12,003,215.
Application No. 17/732,772 is a continuation of application No. 17/154,150, filed on Jan. 21, 2021, now Pat. No. 11,349,432.
Application No. 17/154,150 is a continuation of application No. 15/479,530, filed on Apr. 5, 2017, now Pat. No. 10,931,228.
Application No. 15/479,530 is a continuation of application No. 13/290,528, filed on Nov. 7, 2011, now Pat. No. 9,647,442.

(30) Foreign Application Priority Data
Nov. 9, 2010 (GB) 1018872.0

(51) Int. Cl. H02S 50/00; G01R 31/12; H01L 31/02; H02H 1/00; H02H 7/20

(52) U.S. Cl. CPC H02S 50/00; G01R 31/1227; H01L 31/02021; H02H 1/0015; H02H 7/20; Y02E 10/50

(57) ABSTRACT

A method for arc detection in a system including a photovoltaic panel and a load connectible to the photovoltaic panel with a DC power line. The method measures power delivered to the load thereby producing a first measurement result of the power delivered to the load. Power produced by the photovoltaic panel is also measured, thereby producing a second measurement result of power produced by the photovoltaic panel. The first measurement result is compared with the second measurement result thereby producing a differential power measurement result. Upon the differential power measurement result being more than a threshold value, an alarm condition may also be set. The second measurement result may be modulated and transmitted over the DC power line.

### CROSS REFERENCE TO RELATED APPLICATIONS

The present application is a continuation of U.S. application Ser. No. 17/732,772, filed on Apr. 29, 2022, which is a continuation of U.S. application Ser. No. 17/154,150, filed on Jan. 21, 2021 (now U.S. Pat. No. 11,349,432), which is a continuation of U.S. application Ser. No. 15/479,530, filed on Apr. 5, 2017 (now U.S. Pat. No. 10,931,228), which is a continuation of U.S. application Ser. No. 13/290,528, filed on Nov. 7, 2011 (now U.S. Pat. No. 9,647,442), which claims priority to patent application GB1018872.0, filed Nov. 9, 2010, in the United Kingdom Intellectual Property Office. All the prior applications are incorporated by reference in their entirety.

### FIELD

The present invention is related to distributed power generation systems and specifically to arc detection and prevention in photovoltaic power generation systems.

### BACKGROUND

A distributed photovoltaic power generation system may be variously configured, for example, to incorporate one or more photovoltaic panels mounted in a manner to receive sunlight such as on a roof of a building. An inverter may be connected to the photovoltaic panels. The inverter typically converts the direct current (DC) power from the photovoltaic panels to alternating current (AC) power.

Arcing may occur in switches, circuit breakers, relay contacts, fuses and poor cable terminations. When a circuit is switched off or a bad connection occurs in a connector, an arc discharge may form across the contacts of the connector. An arc discharge is an electrical breakdown of a gas, which produces an ongoing plasma discharge, resulting from a current flowing through a medium such as air, which is normally non-conducting. At the beginning of a disconnection, the separation distance between the two contacts is very small. As a result, the voltage across the air gap between the contacts produces a very large electrical field in terms of volts per millimeter. This large electrical field causes the ignition of an electrical arc between the two sides of the disconnection. If a circuit has enough current and voltage to sustain an arc, the arc can cause damage to equipment such as melting of conductors, destruction of insulation, and fire. The zero crossing of alternating current (AC) power systems may cause an arc not to reignite. A direct current system may be more prone to arcing than AC systems because of the absence of zero crossing in DC power systems.

Electric arcing can have detrimental effects on electric power distribution systems and electronic equipment, and in particular, photovoltaic systems, which are often arranged in a manner that increases the risk of arching. For example, photovoltaic panels often operate at extreme temperatures due to their necessary exposure to the sun. Such conditions cause accelerated deterioration in insulation and other equipment that can lead to exposed wires. Such systems are also exposed to environmental conditions, such as rain, snow, and high humidity. Further, typical residential and/or industrial photovoltaic applications often utilize several panels connected in series to produce high voltage. Exposed conductors with high voltage in wet/humid conditions create an environment in which the probability of arching increases.

This problem of arching raises system maintenance cost and reduces the lifespan of photovoltaic panels, because photovoltaic panels and other related equipment will need to be repaired and/or replaced more frequently. Arching in photovoltaic systems also increases the risk of fire, thereby increasing operating and/or insurance cost on facilities having photovoltaic systems. The net effect of arching in photovoltaic systems is to increase the threshold at which a photovoltaic system becomes cost competitive with nonrenewable sources of energy, such as natural gas, oil, and coal.

### BRIEF SUMMARY

As newly described herein, systems and methods are presented to address the problem of arching in photovoltaic systems, thereby reducing the overall cost, and extending the useful lifespan of such systems. The embodiments described herein, therefore, make deployment of photovoltaic systems in residential and industrial application more competitive with nonrenewable energy alternatives.

Methods are provided for arc detection in a photovoltaic panel system, which may include a load connectible to the photovoltaic panel with one or more mechanisms such as a power line, e.g. a DC power line. An exemplary method may measure power delivered to the load and power produced by the photovoltaic panel. These measurements may be analyzed using a suitable technique. One example of a suitable technique includes a comparison to generate, for example, a differential power measurement result. The differential power measurement result may be further analyzed using, for example, one or more static and/or dynamic threshold values. The analysis may trigger, for example, an alarm condition when the differential power measurement results deviate from one or more threshold values, either at an instant in time or over a time period when the signal is integrated or smoothed. One or more of the measurements (e.g., the second measurement), the static and/or dynamic thresholds, and/or the power measurements may be converted to a suitable format and/or modulation scheme and transmitted to a remote location. In one exemplary method, one or more of the foregoing items (e.g., the second measurement) may be modulated and transmitted (e.g., over the DC power line) to a remote location.

According to further aspects, a device for arc detection in a system may include a photovoltaic panel and a load connectible to the photovoltaic panel using, for example, a power line (e.g. a DC power line). In this aspect, the device may be variously configured to include one or more electronic modules adapted for measuring power produced by one or more photovoltaic panels and/or a distributed and/or centralized controller adapted for measuring power delivered to, for example, the load. Aspects may be variously configured to include one or more mechanisms to analyze power associated with the photovoltaic panel and/or power delivered to the load, dynamically and/or statically, in an instantaneous and/or integrated manner. The analysis may be variously configured to include, for example, dynamic and/or static comparisons of an instantaneous and/or integrated signal. Suitable comparisons may or may not include one or more thresholds. The analysis may collect historical data and determine variations from this historical data. Additionally, the analysis may include predetermined threshold values based on prior test data. Based on the dynamic and/or static comparison, one or more of the mechanisms may be operable to detect arcing when the power output of one or more photovoltaic panels is greater than the power delivered to the load.

According to further aspects, a method for arc detection may be performed in a system having, for example, a photovoltaic string and a load connectible to the photovoltaic string using, for example, a DC power line. The method for arc detection measurement may be variously configured, for example, to quantify a value associated with a noise voltage of the load and/or a noise voltage of one or more of the photovoltaic panels in the photovoltaic string. The quantities associated with the various measured noise voltages may be analyzed using a suitable technique. In one technique, a dynamic and/or static comparison is made between the various noise voltages e.g., (the noise voltage of the load compared with the noise voltage of one or more (e.g. all) of the photovoltaic panels in the photovoltaic string) producing a quantitative value such as a differential noise voltage value(s). The differential noise voltage value(s) may then be analyzed either statically and/or dynamically. In one embodiment, the differential noise voltage values(s) may be compared against one or more threshold values, statically and/or dynamically, instantaneously and/or integrated over time and then compared. Where a threshold is utilized, an alarm condition may be triggered where one or more of the aforementioned values exceed a threshold. For example, upon the differential noise voltage result being more than a threshold value then an alarm condition may be set; upon the alarm condition being set, the photovoltaic string may be disconnected. The various parameters discussed above may be analyzed locally and/or transmitted to a remote location. In one embodiment, one or more of the values may be modulated and transmitted over a DC power line. Upon the power of one or more or all of the photovoltaic panels or the power of photovoltaic string(s) being greater than the power as delivered to the load, then an alarm condition is set according to a previously defined static and/or dynamic criterion.

According to further aspects, one of the methods for arc detection may include software and/or circuits for measuring power delivered to the load and/or power produced by the photovoltaic string

The measurement of the power of the photovoltaic string may be variously configured. In one example, the measurement involves sending instructions to measure the power output of each photovoltaic panel. The power value of each photovoltaic panel may then be transmitted and received. The power value of each photovoltaic panel may be added, thereby giving the second measurement result. The second measurement result may then be subsequently modulated and transmitted over the DC power line.

The load impedance may be changed according to a predetermined value. The power of the photovoltaic string, in this example, may then be measured again, thereby producing a third measurement result of the power of the photovoltaic string. Followed by the power of the load being measured, thereby producing a measurement result of the power of the load. The various measurements may be compared, thereby producing another differential power result. The various differential power results may thereby produce a total differential power result. In this example, upon the total differential power result being more than a threshold value, an alarm condition may be set. Upon the alarm condition being set, the photovoltaic string may be disconnected in the example. The third measurement result may be modulated and transmitted over the DC power line.

In this example, the measuring of the power of the photovoltaic string may involve sending one or more instruction to measure the power of each photovoltaic panel. The power value of each photovoltaic panel may then be transmitted and received. The power value of each photovoltaic panel may be added, thereby giving the third measurement result. The third measurement result may then subsequently modulated and transmitted over the DC power line.

In a further example, the sending of instructions to measure power in the string may be to a master module connected to one of the panels of the string. Embodiments may also include slave modules respectively connected to other panels of the string, which may be instructed to measure power. Power measurement results may then be transmitted from the slave modules to the master module. The power measurement results may then be received by the master module, added up by the master module to produce a string power result, which may be transmitted to a central and/or distributed controller in this example.

### BRIEF DESCRIPTION OF THE DRAWINGS

The invention is herein described, by way of example only, with reference to the accompanying drawings, wherein:

FIG. 1a illustrates an example of circuit showing serial arcing.

FIG. 1b illustrates the circuit of FIG. 1a showing an example of parallel or shunt arcing.

FIG. 2 shows a power generation system including an arc detection feature according to an embodiment of the present invention.

FIG. 3 shows a method according to an embodiment of the present invention.

FIG. 4 shows a method according to an embodiment of the present invention.

FIG. 5a shows a power generation circuit according to an embodiment of the present invention.

FIG. 5b shows a method according to an embodiment of the present invention.

FIG. 5c shows a method step shown in FIG. 5b, in greater detail, the step measures power of a string according to an embodiment of the present invention.

FIG. 5d shows a method for serial arc detection, according to another embodiment of the present invention.

### DETAILED DESCRIPTION

Reference will now be made in detail to embodiments, examples of which are illustrated in the accompanying drawings, wherein like reference numerals refer to the like elements throughout. The embodiments are described below to explain the present invention by referring to the figures.

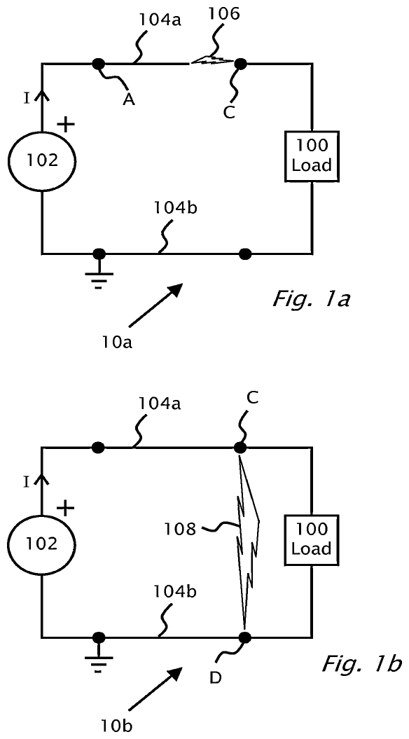

Reference is made to FIG. 1a which shows serial arcing 106 in a circuit 10a according to background art. In FIG. 1a, a direct current (DC) power supply 102 provides power between power lines 104a and 104b. Power line 104b is shown at ground potential. Load 100 connects power line 104b to power line 104a. Serial arcing may occur in any part of circuit 10a in power lines 104a, 104b or internally in load 100 or supply 102 for example. A disconnection or poor connection in power line 104a between point C and point A is shown which causes an instance 106 of serial arcing. Typically, if series arc 106 can be detected, circuit breakers (not shown) located at supply 102 or load 100 can be tripped to prevent continuous serial arcing 106.

Reference is made to FIG. 1b, which shows parallel or shunt arcing 108 in a circuit 10b according to background art. In circuit 10b, a direct current (DC) power supply 102 provides power between power lines 104a and 104b. Load 100 connects power lines 104a and 104b. Parallel arcing may occur in many parts of circuit 10b, examples may include arcing between the positive of supply 102 and the ground/chassis of supply 102, if power supply cable 104a/b is a two core cable; arcing may occur between the two cores, or between the positive terminal 104a and ground 104b of load 100. Parallel arcing 108 may occur as shown between power line 104b at point D and high potential on power line 104a at point C.

Arc noise is approximate to white noise, meaning that the power spectral density is nearly equal throughout the frequency spectrum. Additionally, the amplitude of the arc noise signal has very nearly a Gaussian probability density function. The root mean square (RMS) arc noise voltage signal (Vₙ) is given in equation Eq. 1, as follows:

$${V}_{N} = \sqrt{4 KTBR} , \qquad Eq . 1$$

where:
K=Boltzmann's constant=1.38×10⁻²³ Joules per Kelvin;
T=the temperature in degrees Kelvin;
B=bandwidth in Hertz (Hz) over which the noise voltage (V_{N}) is measured; and
R=resistance (ohms) of a resistor/circuit/load.

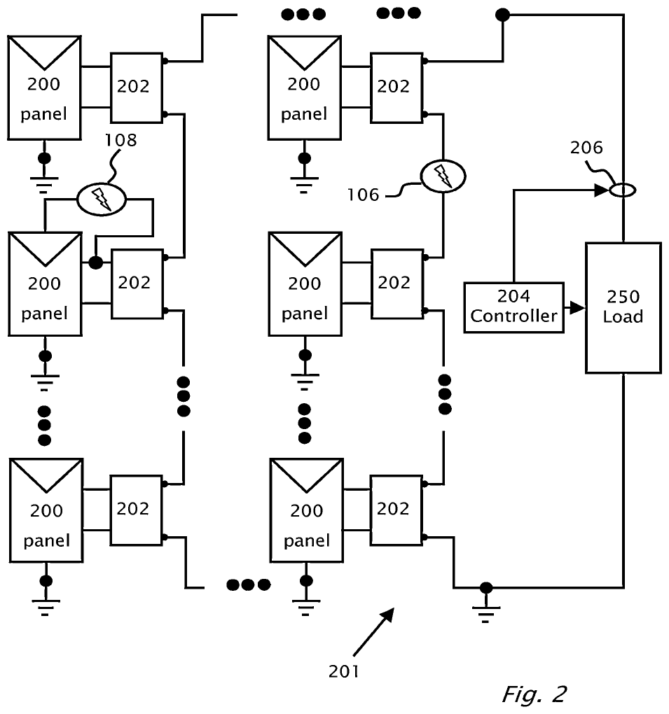

Reference is now made to FIG. 2, which shows a power generation system 201 including an arc detection feature according to an embodiment. A photovoltaic panel 200 is preferable connected to an input of a module 202. Multiple panels 200 and multiple modules 202 may be connected together to form a serial string. The serial string may be formed by connecting the outputs of modules 202 in series. Multiple serial strings may be connected in parallel across a load 250. Load 250 may be, for example, a direct current (DC) to alternating current (AC) inverter or DC-to-DC converter. An electronic module 202 may be included to measures the voltage and/or current produced by a panel 200. Module 202 may be capable of indicating the power output of a panel 200. Attached to load 250 may be a controller 204. Controller 204 may be operatively attached to modules 202 via power line communications over DC power lines connecting load 250 to the serial strings and/or by a wireless connection. Controller 204 may be configured to measure via sensor 206, the power received by load 250. Each panel 200 has a chassis, which may be connected to ground. An instance of serial arcing 106 may occur between two panels 200. An instance of parallel arcing 108 may be shown between the positive terminal of a panel 200 and ground of the panel 200.

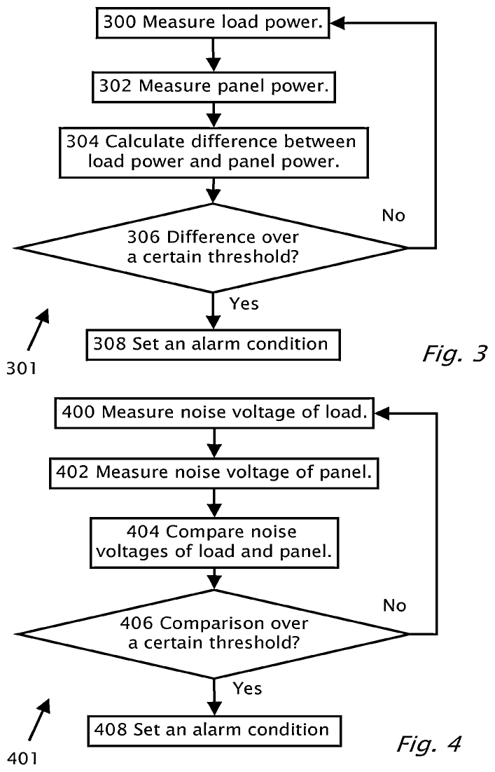

Reference is now made to FIG. 3, which shows a method 301 according to one embodiment. Method 301 may be configured to detect serial and/or parallel arcing. Central controller 204 may be configured to measure one or more parameters such as the power received by load 250 (step 300). Module 202 may be variously configured such as to measure the power of one or more panels 200 (step 302). Module 202 may be variously configured. In one embodiment, it transmits a datum representing the power measured of the one or more panels 200 via wireless or power line communications to controller 204. Controller 204 calculates the difference between power generated at panel(s) 200 and the power received at load 250 (step 304). In this example, if the difference calculated in step 304 shows that the power generated at panel(s) 200 may be greater than the power received at load 250 (step 306) according to a predefined criteria, an alarm condition of potential arcing may be set (step 308). Otherwise, in this example, the arc detection continues with step 300.

Reference is now made to FIG. 4, which shows an illustrative method 401. Method 401 is a method, which may be utilized for detecting serial and/or parallel arcing. In a method according to this example, central controller 204 measures (step 400) the root mean square (RMS) noise voltage of load 250. Module 202 may then measure (step 402) the root mean square (RMS) noise voltage of one or more panels 200. Module 202 may be configured to transmit a datum representing the RMS noise voltage measured of panel(s) 200 via wireless or power line communications to controller 204.

One or more controllers may be configured to compare the noise voltage at panel (s) 200 with the noise voltage at the load 250 by, for example, calculating the difference between noise voltage measured at panel 200 and the noise voltage measured at load 250 (step 404). In this example, if the difference calculated in step 404 shows that noise voltage measured at panel(s) 200 may be greater than the noise voltage measured at load 250 (step 406) according to one or more predefined criteria, an alarm condition of potential arcing may be set (step 408).

Further to this example, the comparison (step 404) also may involve comparisons of previously stored RMS noise voltage levels of panel§ 200 and/or load 250 in a memory of controller 204 at various times, for example, the time immediately after installation of power generation system 201. The previously stored RMS noise voltage levels of both panel§ 200 and load 250 are, in this example, in the form of a look-up-table stored in the memory of controller 204. The look-up-table has RMS noise voltage levels of both panel(s) 200 and load 250 at various times of the day, day of the week or time of year for example, which can be compared to presently measured RMS noise voltage levels of both panel(s) 200 and load 250.

In this exemplary example, if the comparison of the measured load 250 RMS noise voltage datum with the measured panel(s) 200 RMS noise voltage datum may be over a certain threshold (step 406) of RMS noise voltage difference an alarm condition of potential arcing may be set (step 408) otherwise arc detection continues with step 400.

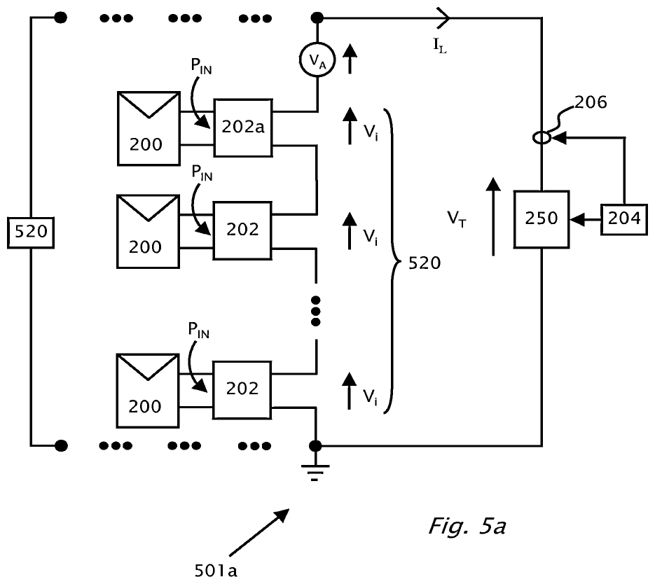

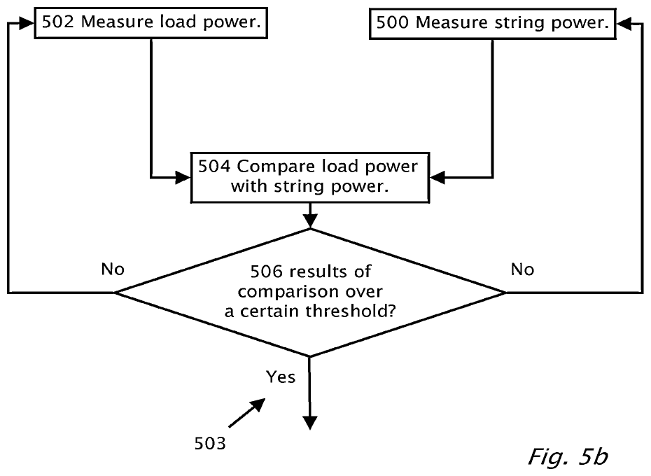

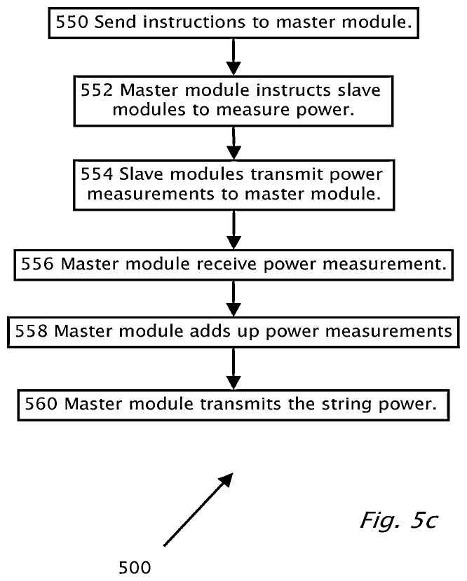

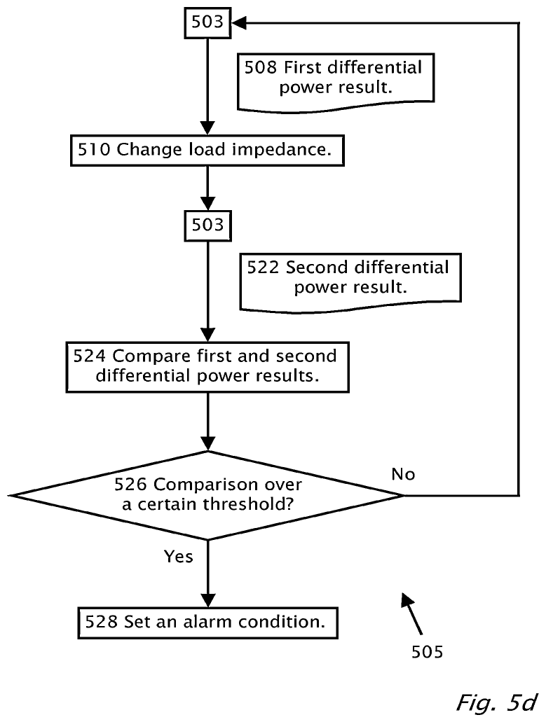

Reference is now made to FIG. 5a which shows a power generation circuit 501a according to an embodiment of the present invention. Power generation circuits 501a have outputs of panels 200 connected to the input of modules 202. The outputs of panels 200 may be configured to provide a DC power input (P_{IN}) to modules 202. Modules 202 may include direct current (DC-to-DC) switching power converters such as a buck circuit, a boost circuit, a buck-boost circuit, configurable buck-or-boost circuits, a cascaded buck and boost circuit with configurable bypasses to disable the buck or boost stages, or any other DC-DC converter circuit. The output voltage of modules 202 may be labeled as Vᵢ.

The outputs of modules 202 and module 202a may be connected in series to form a serial string 520. Two strings 520 may be shown connected in parallel. In one string 520, a situation is shown of an arc voltage (V_{A}) which may be occurring serially in string 520. Load 250 may be a DC to AC inverter. Attached to load 250 may be a central controller 204. Controller 204 optionally measures the voltage (VT) across load 250 as well as the current of load 250 via current sensor 206. Current sensor 206 may be attached to controller 204 and coupled to the power line connection of load 250.

Depending on the solar radiation on panels 200, in a first case, some modules 202 may operate to convert power on the inputs to give fixed output voltages (Vᵢ) and the output power of a module 202 that may be dependent on the current flowing in string 520. The current flowing in string 520 may be related to the level of irradiation of panels 200, e.g., the more irradiation, the more current in string 520, and the output power of a module 202 is more.

In a second case, modules 202 may be operating to convert powers on the input to be the same powers on the output; so for example if 200 watts is on the input of a module 202, module 202 may endeavor to have 200 watts on the output. However, because modules 202 may be connected serially in a string 520, the current flowing in string 520 may be the same by virtue of Kirchhoff's law. The current flowing in string 520 being the same means that the output voltage (Vᵢ) of a module should vary in order to establish that the power on the output of a module 202 may be the same as the power on the input of a module 202. Therefore, in this example, as string 520 current increases, the output voltage (Vᵢ) of modules 202 decreases or as string 520 current decreases, the output voltage (Vᵢ) of modules 202 increases to a maximum value. When the output voltage (Vᵢ) of modules 202 increases to the maximum value, the second case may be similar to the first case in that the output voltage (Vᵢ) may be now effectively fixed.

Modules 202 in string 520 may have a master/slave relationship with one of modules 202a configured as master and other modules 202 configured as slaves.

Since current may be the same throughout string 520 in this example, master module may be configured to measure current of string 520. Modules 202 optionally measure their output voltage Vᵢ so that the total string power may be determined. Output voltages of slave modules 202, in this example, may be measured and communicated by wireless or over power line communications, for instance to master unit 202a so that a single telemetry from module 202a to controller 204 may be sufficient to communicate the output power of the string. Master module 202a in string 520 may be variously configured, such as to communicate with the other slave modules 202 for control of slave modules 202. Master module 202a, in this example, may be configured to receive a ‘keep alive’ signal from controller 204, which may be conveyed to slave modules 202. The optional ‘keep alive’ signal sent from controller 204 communicated by wireless or over power line communications, may be present or absent. The presence of the ‘keep alive’ signal may cause the continued operation of modules 202 and/or via master module 202a. The absence of the ‘keep alive’ signal may cause the ceasing of operation of modules 202 and/or via master module 202a (i.e. current ceases to flow in string 520). Multiple ‘keep alive’ signals each having different frequencies corresponding to each string 520 may be used so that a specific string 520 may be stopped from producing power where there may be a case of arcing whilst other strings 520 continue to produce power.

Reference is now also made to FIG. 5b which shows a method 503 according to an embodiment of the present invention. In step 500, one or more strings 520 power may be measured. In step 502, the load 250 power may be measured using central controller 204 and sensor 206. The measured load power and the measured string powers may be compared in step 504. Steps 500, 502 and 504 may be represented mathematically by Equation Eq. 2 (assuming one string 520) with reference, in this example, to FIG. 5a, as follows:

$${V}_{T} {I}_{L} = \sum {P}_{IN} - {V}_{A} [ {I}_{L} ] {I}_{L} + \sum {V}_{i} {I}_{L} , \qquad Eq . 2$$

where:
V_{A}[I_{L}]=the arc voltage as a function of current I_{L};
V_{T}I_{L}=the power of load 250;
ΣP_{IN}=the power output of modules 202 when modules 202 may be operating such that the output voltage (Vᵢ) of a module varies in order to establish that the power on the output of a module 202 may be the same as the power on the input of a module 202 (P_{IN}); and
ΣVᵢI_{L}=the power output of modules 202 with fixed voltage outputs (Vᵢ) and/or power output of modules 202 (with variable output voltage Vᵢ) when string 520 current decreases sufficiently such that the output voltage (Vᵢ) of modules 202 increases to a maximum output voltage level value. In all cases, the maximum output voltage level value (Vᵢ) and fixed voltage outputs (Vᵢ) may be pre-configured to be the same in power generation circuit 501a.

The comparison between string power of string 520 and of the power (V_{T}×I_{L}) delivered to load 250 may be achieved by subtracting the sum of the string 520 power (ΣP_{IN}+ΣVᵢI_{L}) from the power delivered to load 250 (V_{T}×I_{L}) to produce a difference. If the difference may be less than a pre-defined threshold (step 506), the measurement of power available to string 520 (step 500) and load 250 (step 502) continues. In decision block 506, if the difference may be greater than the previously defined threshold, then an alarm condition may be set and a series arc condition may be occurring. A situation of series arcing typically causes the transmission of a ‘keep alive’ signal to modules 202 from controller 204 to discontinue, which causes modules 202 to shut down. Modules 202 shutting down may be a preferred way to stop series arcing in string 520.

Reference is now made to FIG. 5c which shows method step 500 (shown in FIG. 5b) in greater detail to measure power of string 502 according to an embodiment of the present invention. Central controller 204 may send instructions (step 550) via power line communications to master module 202a. Master module 202a may measure the string 502 current as well as voltage on the output of master module 202a and/or voltage and current on the input of master module 202a to give output power and input power of module 202a respectively. Master module may instruct (step 552) slave modules 202 in string 502 to measure the output voltage and string 502 current and/or the input voltage and current of modules 202 to give output power and input power of modules 202 respectively. Slave modules 202 may then be configured to transmit (step 554) to master module 202a the input and output powers measured in step 552. Master module 202a receives (step 556) the transmitted power measurements made in step 554. Master module 202a then adds up the received power measurements along with the power measurement made by master module 202a (step 558) according to equation Eq.2. According to equation Eq.2; ΣP_{IN}=the power output of modules 202 when modules 202 may be operating such that the output voltage (Vᵢ) of a module varies in order to establish that the power on the output of a module 202 may be the same as the power on the input of a module 202 (P_{IN}); ΣVᵢI_{L}=the power output of modules 202 with fixed voltage outputs (Vᵢ) and/or power output of modules 202 (with variable output voltage Vᵢ) when a string 520 current decreases sufficiently such that the output voltage (Vᵢ) of modules 202 increases to a maximum output voltage level value. In all cases, the maximum output voltage level value (Vᵢ) and fixed voltage outputs (Vᵢ) may be pre-configured to be the same in power generation circuit 501a. The added up power measurements in step 558 may be then transmitted by master module 202a to central controller 204 (step 560).

Reference is now made to FIG. 5d, which shows a method 505 for serial arc detection, according to another embodiment of the present invention. First differential power result 508 occurs in circuit 501a, with load current I_{L} now labeled as current I₁ and with voltage V_{T} across load 250 (as shown in FIG. 5a). First differential power result 508 may be produced with reference to FIG. 5a and equation Eq.3 (below) as a result of performing method 503 (shown in FIG. 5c). Eq. 3 is as follows:

$${V}_{T} {I}_{1} = \sum {P}_{IN} - {V}_{A} [ {I}_{1} ] {I}_{1} + \sum {V}_{i} {I}_{1} , \qquad Eq . 3$$

where:
V_{A}[I₁]=the arc voltage as a function of current I₁;
V_{T}I₁=the power of load 250;
ΣP_{IN}=the power output of modules 202 when modules 202 may be operating such that the output voltage (Vᵢ) of a module varies in order to establish that the power on the output of a module 202 may be the same as the power on the input of a module 202 (P_{IN}); and
ΣVᵢI_{L}=the power output of modules 202 with fixed voltage outputs (Vᵢ) and/or power output of modules 202 (with variable output voltage Vᵢ) when string 520 current decreases sufficiently such that the output voltage (Vᵢ) of modules 202 increases to a maximum output voltage level value. In all cases, the maximum output voltage level value (Vᵢ) and fixed voltage outputs (Vᵢ) may be pre-configured to be the same in power generation circuit 501a.

The impedance of load 250 may be adjusted (step 510) optionally under control of central controller 204. Typically, if load 250 is an inverter, controller 204 adjusts the input impedance of load 250 by variation of a control parameter of the inverter. A change in the input impedance of load 250 causes the voltage across the input of load 250 to change by virtue of Ohm's law. The voltage (V_{T}) as shown in circuit 501a across load 250 may be therefore made to vary an amount ΔV as a result of the input impedance of load 250 being adjusted. The voltage across load 250 may be now V_{T}+ΔV and the load 250 current (I_{L}) may be now I₂.

A second differential power result 522 may be now produced as a result of performing again method 503 (shown in FIG. 5c) on the adjusted input impedance of load 250 performed in step 510. Second differential power result 522 may be represented mathematically by equation Eq. 4, as follows:

$$( {V}_{T} + Δ V ) {I}_{2} = \sum {P}_{IN} - {V}_{A} [ {I}_{2} ] {I}_{2} + \sum {V}_{i} {I}_{2} , \qquad Eq . 4$$

where:
V_{A}[I₂]=the arc voltage as a function of current I₂;
(V_{T}+ΔV)I₂=the power delivered to load 250;
ΣP_{IN}=the power output of modules 202 when modules 202 may be operating such that the output voltage (Vᵢ) of a module varies in order to establish that the power on the output of a module 202 may be the same as the power on the input of a module 202 (P_{IN}); and
ΣVᵢI_{L}=the power output of modules 202 with fixed voltage outputs (Vᵢ) and/or power output of modules 202 (with variable output voltage Vᵢ) when string 520 current decreases sufficiently such that the output voltage (Vᵢ) of modules 202 increases to a maximum output voltage level value. In all cases, the maximum output voltage level value (Vᵢ) and fixed voltage outputs (Vᵢ) may be pre-configured to be the same in power generation circuit 501a.

The first differential power result 508 may be compared with the second differential power result 522 (step 524), for example, using controller 204 to subtract the first differential power result 508 from the second differential power result 522 to produce a difference. The difference may be expressed by equation Eq. 5, which may be as a result of subtracting equation Eq.3 from equation Eq.4, as follows:

$${V}_{T} {I}_{1} - ( {V}_{T} + ΔV ) {I}_{2} = {V}_{A} [ {I}_{2} ] {I}_{2} - {V}_{A} [ {I}_{1} ] {I}_{1} + \sum {V}_{i} ( {I}_{1} - {I}_{2} ) \qquad Eq . 5$$

The summed output power (P_{IN}) of each module 202 for circuit 501a may be thus eliminated.

Equation Eq. 5 may be re-arranged by controller 204 by performing a modulo operator function on equation Eq.5 to obtain an arc coefficient α as shown in equation Eq. 6.

$$\frac{{V}_{T} {I}_{1} - ( {V}_{T} + Δ V ) {I}_{2}}{( {I}_{1} - {I}_{2} )} = α + \sum {V}_{i} \qquad Eq . 6$$

where the arc coefficient α is shown in Eq.7

$$α = \frac{{V}_{A} [ {I}_{2} ] {I}_{2} - {V}_{A} [ {I}_{1} ] {I}_{1}}{( {I}_{1} - {I}_{2} )} \qquad Eq . 7$$

Controller 204, for example, may be configured to calculate coefficient α according to the above formula and measurements. A non-zero value of arc coefficient α shown in equation Eq. 7 causes an alarm condition to be set (step 528) otherwise another first differential power result 508 may be produced (step 503). A situation of series arcing typically causes the ‘keep alive’ signal to be removed by controller 204, causing modules 202 to shut down. Modules 202 shutting down may be a preferred way to stop series arcing in string 520.

The definite articles “a”, “an” is used herein, such as “an arc voltage and/or arc current”, “a load” have the meaning of “one or more” that is “one or more arc voltages and/or arc currents” or “one or more loads”.

While the embodiments of aspects of the invention has been described with respect to a limited number of examples, it will be appreciated that many variations, modifications and other applications of the invention may be made.

1. A system comprising:
a plurality of power converters, wherein each power converter of the plurality of power converters is configured to:
convert an input power to an output power;
determine a first electrical parameter related to the power converter;
determine a second electrical parameter related to the power converter;
determine a parameter difference based on a comparison between the first electrical parameter and the second electrical parameter;
compare the parameter difference to a threshold value; and
set an alarm condition based on the parameter difference being greater than the threshold value.

2. The system of claim 1, wherein the first electrical parameter is a first power, the second electrical parameter is a second power, and the parameter difference is a power difference.

3. The system of claim 1, wherein the first electrical parameter is a first noise, the second electrical parameter is a second noise, and the parameter difference is a noise difference.

4. The system of claim 1, wherein each power converter is configured to shut down based on the parameter difference being greater than the threshold value.

5. The system of claim 1, wherein each power converter of the plurality of power converters is configured to communicate with at least one other power converter.

6. The system of claim 5, wherein each power converter of the plurality of power converters is configured to communicate using power line communication.

7. The system of claim 5, wherein each power converter of the plurality of power converters is configured to communicate using wireless communication.

8. A method comprising:
converting, with each power converter of a plurality of power converters, an input power to an output power;
determining, by each power converter of the plurality of power converters, a first electrical parameter related to the power converter;
determining, by each power converter of the plurality of power converters, a second electrical parameter related to the power converter;
determining, by each power converter of the plurality of power converters, a parameter difference based on a comparison between the first electrical parameter and the second electrical parameter;
comparing, by each power converter of a plurality of power converters, the parameter difference to a threshold value; and
setting, by each power converter of a plurality of power converters, an alarm condition based on the parameter difference being greater than the threshold value.

9. The method of claim 8, wherein the first electrical parameter is a first power, the second electrical parameter is a second power, and the parameter difference is a power difference.

10. The method of claim 8, wherein the first electrical parameter is a first noise, the second electrical parameter is a second noise, and the parameter difference is a noise difference.

11. The method of claim 8, further comprising shutting down each power converter of the plurality of power converters based on the parameter difference being greater than the threshold value.

12. The method of claim 8, further comprising communicating, by each power converter of the plurality of power converters, with at least one other power converter.

13. The method of claim 12, wherein the communicating, by each power converter of the plurality of power converters, is using power line communication.

14. The method of claim 12, wherein the communicating, by each power converter of the plurality of power converters, is using wireless communication.

15. An electronic module comprising a power converter configured to:
convert an input power to an output power;
determine a first electrical parameter related to the power converter;
determine a second electrical parameter related to the power converter;
determine a parameter difference based on a comparison between the first electrical parameter and the second electrical parameter;
compare the parameter difference to a threshold value; and
set an alarm condition based on the parameter difference being greater than the threshold value.

16. The electronic module of claim 15, wherein the first electrical parameter is a first power, the second electrical parameter is a second power, and the parameter difference is a power difference.

17. The electronic module of claim 15, wherein the first electrical parameter is a first noise, the second electrical parameter is a second noise, and the parameter difference is a noise difference.

18. The electronic module of claim 15, wherein the power converter is configured to shut down based on the parameter difference being greater than the threshold value.

19. The electronic module of claim 15, wherein the power converter is configured to communicate with at least one other power converter.

20. The electronic module of claim 19, wherein the power converter is configured to communicate using at least one of: power line communication and wireless communication.
